(19) United States
(12) Patent Application Publication
(10) Pub. No.: US 2026/0169069 A1
(43) Pub. Date: Jun. 18, 2026

(54) HYBRID OVER-CURRENT DETECTION METHOD FOR SOLID-STATE CIRCUIT BREAKER (SSCB)

(71) Applicant: Microchip Technology Incorporated, Chandler, AZ (US)

(72) Inventors: Ehab Tarmoom, Allen Park, MI (US); David Gammie, Chandler, AZ (US)

(21) Appl. No.: 19/358,219

(22) Filed: Oct. 14, 2025

Related U.S. Application Data
(60) Provisional application No. 63/735,541, filed on Dec. 18, 2024.

(51) Int. Cl. G01R 31/327; G01R 15/14; G01R 15/20; G01R 19/165; G01R 19/25

(52) U.S. Cl. CPC G01R 31/327; G01R 15/146; G01R 15/20; G01R 19/16571; G01R 19/16576; G01R 19/25

(57) ABSTRACT

Disclosed herein are aspects for detecting and responding to over-current conditions in a solid-state circuit breaker (SSCB) system. An example aspect for a solid-state circuit breaker system includes a shunt resistor to generate a voltage proportional to a current flowing through a circuit, a plurality of fault detection units, an OR gate to receive timer output signals from the plurality of fault detection units and generate a fault detection signal, and an SR latch having a set input to receive the fault detection signal from the OR gate, the SR latch configured to provide a control signal to a gate driver of a solid-state switch based on the fault detection signal. Each fault detection unit can include a digital-to analog converter to set a threshold voltage, a comparator to compare voltages, and a timer to validate a fault condition and generate the timer output signals.

### CROSS-REFERENCE TO RELATED APPLICATION

The present application claims priority from U.S. Provisional Patent Application No. 63/735,541, filed Dec. 18, 2024, which is incorporated herein by reference in its entirety.

### TECHNICAL FIELD

The present disclosure relates generally to solid-state circuit breakers (SSCBs), and more specifically to a hybrid over-current detection method for SSCBs.

### SUMMARY

According to an aspect of one or more examples, there is provided a solid-state circuit breaker (SSCB) system. The system may include a shunt resistor to generate a voltage proportional to a current flowing through a circuit, a plurality of fault detection units, each including a digital-to-analog converter (DAC) to set a threshold voltage, a comparator to compare the voltage generated by the shunt resistor with the threshold voltage set by the DAC, and a timer to validate a fault condition and generate a timer output signal based on an output of the comparator, an OR gate to receive the timer output signals from the plurality of fault detection units and generate a fault detection signal, and an SR latch having a set input to receive the fault detection signal from the OR gate, the SR latch configured to provide a control signal to a gate driver of a solid-state switch based on the fault detection signal. The plurality of fault detection units may detect multiple levels of over-current conditions. The comparator may include hysteresis to prevent false triggering due to transient current fluctuations. The system may also include an analog-to-digital converter (ADC) to continuously sample the voltage across the shunt resistor. The system may also include firmware to analyze an output of the ADC to detect over-current conditions that do not meet predefined hardware thresholds and output a firmware output signal indicating whether an over-current condition exists. The OR gate may be configured to receive the firmware output signal and output the fault detection signal based on the timer output signals and the firmware output signal. The SR latch may include a set input to receive the aggregated output of the OR gate, and a reset input to reset the SR latch based on the firmware output signal. The OR gate may include N+1 inputs. N inputs may be connected to outputs of the plurality of fault detection units and one input may be connected to a software-based fault detection path. The system may also include a bi-directional fault detection configuration. Each fault detection unit may include two DACs and two comparators respectively coupled to the two DACs, and the comparators may monitor current in positive and negative directions. Each DAC in the fault detection units may be programmable to adjust the threshold voltage. The control signal may be configured to control the gate driver to reduce drive strength during an over-current condition and fully disable the circuit during a short-circuit condition.

According to one or more examples, there is provided a method of detecting and responding to over-current conditions in a solid-state circuit breaker (SSCB) system. The method may include generating a voltage proportional to a current flowing through a circuit using a shunt resistor, comparing the generated voltage with a plurality of threshold voltages set by a plurality of digital-to-analog converters (DAC) using a plurality of comparators, validating a fault condition by requiring a result of the comparisons to persist for a predefined duration using a timer and generating a plurality of timer output signals, aggregating the plurality of timer output signals using an OR gate and generating a fault detection signal, and providing the aggregated outputs to an SR latch to generate a control signal for a solid-state switch to reduce drive strength to, or disable, the circuit based on the fault detection signal. The method may also include monitoring bi-directional current flows using two comparators and two DACs in each fault detection unit. For example, a first comparator of the plurality of comparators monitors current in a first direction and a second comparator of the plurality of comparators monitors current in a second direction. The method may also include adjusting threshold voltages of the DACs. The plurality of comparators may include hysteresis to reduce false triggering due to transient current fluctuations. The method may also include sampling voltage across the shunt resistor using an analog-to-digital converter (ADC) and processing the sampled voltage using firmware to detect additional fault conditions. The firmware may adjust fault detection thresholds based on historical fault data or load conditions. The timer may filter transient current spikes to prevent unnecessary fault responses. The method may also include prioritizing hardware-detected fault conditions over software-detected conditions. The gate driver may reduce drive strength during an over-current condition and disable the circuit during a short-circuit condition. The method may also include combining outputs from bi-directional fault detection units through logical OR operation before passing them to the timer. The method may reset the SR latch based on an output of the firmware.

According to an aspect of one or more examples, there is provided a solid-state circuit breaker (SSCB) system. The system may include a current sensing element to generate a voltage proportional to a current flowing through a circuit, a plurality of hardware-based signal paths configured to receive the voltage generated by the current sensing element and detect faults based on a plurality of respective thresholds, a software-based signal path configured to receive the voltage generated by the current sensing element and detect faults outside of the plurality of thresholds, a logic gate to aggregate outputs from the plurality of hardware-based signal paths and the software-based signal path, and an SR latch to provide a control signal to a gate driver of a solid-state switch based on an output from the logic gate. The output of the software-based signal path may be configured to reset the SR latch. One or more of the plurality of hardware-based signal paths may be configured to monitor current in the circuit in a first direction and a second direction that is opposite the first direction. The plurality of hardware-based signal paths may be configured to detect faults based on the voltage generated by the current sensing element exceeding the one or more of the plurality of respective thresholds for a predefined duration. The current sensing element may be a shunt resistor or a magnetic sensor.

### BRIEF DESCRIPTION OF DRAWINGS

FIG. 1 shows a solid-state circuit breaker (SSCB) system that integrates both hardware and software-based fault detection and protection mechanisms according to the prior art.

FIG. 2 shows a SSCB system that integrates both hardware and software-based fault detection and protection mechanisms according to one or more examples.

FIG. 3A shows a fault detection unit (FDU) according to FIG. 2.

FIG. 3B shows a FDU according to one or more examples.

FIG. 4 shows a method of detecting and responding to over-current conditions in a SSCB system according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Solid-state circuit breakers (SSCBs) are an emerging technology aimed at replacing traditional circuit protection devices such as thermal fuses and electromechanical circuit breakers. The time-current characteristic (TCC) curves of most existing SSCBs are designed to replicate the trip profiles of these conventional devices, which are defined by various electrical standards. This approach, while ensuring compliance with established standards, often leads to over-design, requiring more power devices than are actually needed. Consequently, this increases costs and reduces the efficiency of SSCB implementations.

As SSCBs gain greater acceptance in the market, their design may no longer need to strictly adhere to the same standards that were originally developed for mechanical solutions. Unlike their mechanical counterparts, SSCBs are electronic and offer greater configurability. This allows their TCC curves to be improved based on specific wiring and loads, rather than conforming to fixed, predefined profiles.

One consideration in the design of SSCBs is functional safety. Circuit protection mechanisms that rely exclusively on software may introduce potential reliability and safety concerns. For example, existing solutions depend on software for handling over-currents up to the short-circuit threshold. Similarly, many other implementations, primarily found in academic research, utilize digital signal processors (DSPs) and software-based approaches for circuit protection. While these methods provide flexibility, they may lack robustness for real world applications. Therefore, the configurability of SSCBs, combined with the need for reliable and efficient circuit protection, underscores the importance of advancing SSCB technology to address these challenges effectively.

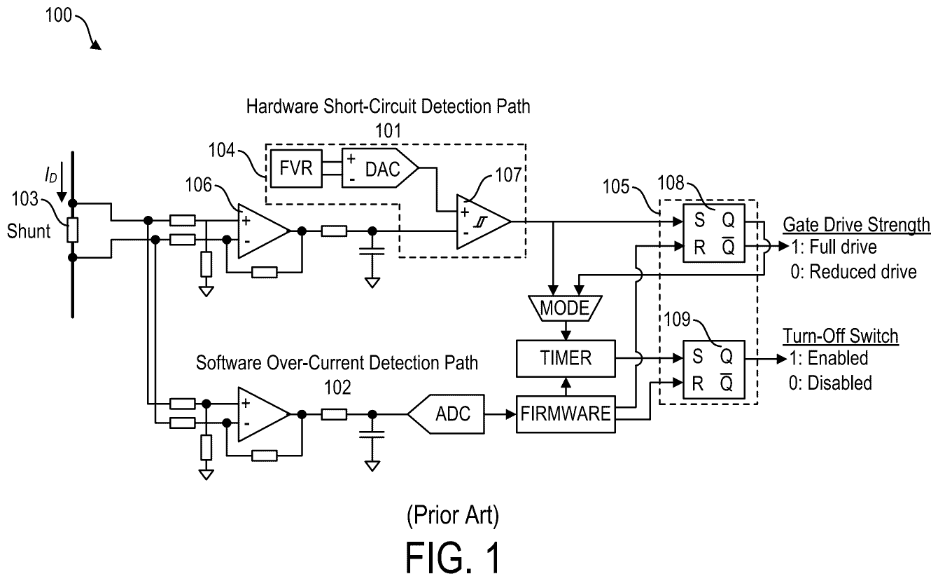

FIG. 1 shows a solid-state circuit breaker (SSCB) system 100 that integrates both hardware and software-based fault detection and protection mechanisms according to the prior art. As shown in FIG. 1, the system 100 may include a hardware short-circuit detection path 101 and a software over-current detection path 102. The hardware short-circuit detection path 101 may provide immediate fault response for short-circuit conditions. The hardware short-circuit detection path 101 may include a shunt resistor 103, a fault detection unit (FDU) 104, and control logic 105. The shunt resistor 103 may be positioned in the current path and may generate a voltage proportional to the current (I_{D}) flowing through the circuit. The voltage across the shunt resistor 103 may be amplified (e.g., by an operational amplifier 106) and compared (e.g., by a comparator 107) against a threshold voltage set by a digital-to-analog converter (DAC). The DAC may receive input from a fixed voltage reference (FVR), enabling precise tuning of the short-circuit detection level. If the current exceeds the threshold, the comparator 107 may output a fault signal.

The fault signal from the comparator 107 may be fed directly into control logic 105. Control logic 105 may output a gate drive strength control signal and a turn-off switch control signal. The gate drive strength control signal may be configured to toggle between full drive (1) and reduced drive (0) modes. This feature may limit the power supplied to the circuit during fault conditions, preventing further damage. The turn-off switch control signal may be configured to detect a short-circuit condition. If a short-circuit condition is detected, the control logic 105 may disable the circuit by triggering the turn-off switch. The turn-off switch may be enabled (1) or disabled (0). The hardware path 101 may ensure a near instantaneous response to faults, addressing functional safety by operating independently of software delays.

The software over-current detection path 102 may provide a complimentary layer of protection for over-current conditions. The software over-current detection path 102 may include an analog-to-digital converter (ADC), firmware processing (FIRMWARE), timer (TIMER) and mode selection (MODE), and the shared control logic 105. The voltage across the shunt resistor 103 may be continuously sampled by the ADC, providing a digital representation of the current. The ADC output may be processed by the firmware to determine if the current exceeds predefined thresholds. The thresholds may be adjustable based on load and wiring configurations. The firmware may include configurable timers that define how long an over-current condition may persist before initiating a response. This may allow for flexible customization for different applications. When the firmware identifies an over-current condition, it may send a signal to the shared control logic 105. This signal may adjust gate drive strength to reduce power delivered to the load or trigger the turn-off switch if the over-current condition is deemed severe.

The outputs from the hardware and software detection paths 101 and 102 may be combined through shared control logic 105 implemented via SR latches (Set-Reset Flip Flops). Control logic 105 may include a hardware SR latch 108 and a software SR latch 109. The hardware SR latch 108 may have a set input (S), a reset input (R), an output (Q), and a complimentary output (Q). The set input may be triggered by the hardware short-circuit detection comparator 107. The reset input may be triggered by a system reset or when the fault condition is cleared. The complimentary output may control the gate drive strength, enabling full drive (1) during normal operation and reduced drive (0) during a detected fault. The output may be used for logic coordination with the turn-off switch. The hardware SR latch 108 may ensure an immediate and persistent response to short-circuit events until the fault is resolved. The software SR latch 109 may have a set input(S), a reset input (R), an output (Q), and a complimentary output (Q). The set input may be triggered by firmware processing when an over-current condition is detected. The reset input may be triggered by firmware when the condition no longer persists or a system reset occurs. The output may signal the gate drive to reduce power or trigger the turn-off switch, depending on the condition. The complimentary output may coordinate with other system logic to ensure safe fault recovery.

The gate drive strength control of the control logic 105 may allow the system 100 to modulate gate drive strength, toggling between full and reduced drive modes based on detected over-current conditions. This may reduce thermal stress on components during over-current conditions. The turn-off switch control of the control logic 105 may allow the system 100 to disable the circuit entirely based on detected short-circuit conditions, ensuring protection for downstream components.

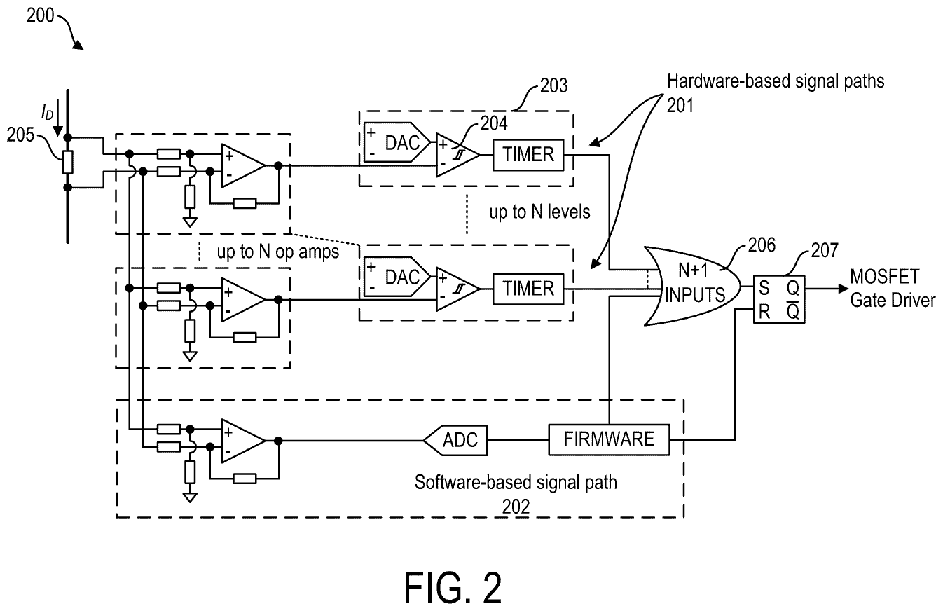

FIG. 2 shows a SSCB system 200 that integrates both hardware and software-based fault detection and protection mechanisms according to one or more examples of the present disclosure. The system 200 may build upon the system 100 of FIG. 1 by introducing additional levels of fault detection granularity and scalability, addressing limitations of the system 100. As shown in FIG. 2, the system 200 may include multiple hardware-based signal paths 201 and a software-based signal path 202. Each hardware-based signal path 201 may include a fault detection unit (FDU) 203 including a comparator 204 and connected to a current sensing element 205, with each comparator 204 associated with a distinct digital-to-analog converter (DAC). The DACs may allow precise threshold adjustments for multiple fault levels. Each comparator 204 output may be fed into a timer (TIMER). The timers may add configurability by setting a minimum duration for which a fault condition persists before triggering a response. This may reduce false positives caused by transient events. The system 200 may support up to N levels of detection, where each level corresponds to a specific over-current or fault threshold. The outputs from the timers may represent hardware-detected fault conditions for different levels of severity.

The software-based signal path 202 may operate in parallel with the hardware path 201 and provide additional monitoring and configurability. The software path 202 may use an analog-to-digital converter (ADC) to sample the voltage across the current sensing element 205, digitizing current data for further processing. The firmware (FIRMWARE) may analyze the ADC data to detect fault conditions that fall outside the pre-configured hardware thresholds. This may include gradual or borderline over-currents. The software-based path 202 may send fault signals to the central logic if it detects a condition requiring intervention. These signals may be considered alongside hardware-detected faults.

In aspects of system 200, current sensing element 205 can be one or more sensing elements positioned in the current path and configured to generate a voltage proportional to the current (ID) flowing through the circuit. For example, in some aspects, current sensing element 205 can be a shunt resistor. In another example, in some aspects, current sensing element 205 can be one or more magnetic sensors. The magnetic sensors can be configured as an integrated circuit that senses current that conducts through the chip or senses the magnetic field that a current generates. In some aspects, the magnetic sensors can be powered by a 3.3 V or 5 V supply, or can have a dual supply, such as ±15 V. The output of the magnetic sensors can be an analog signal with a voltage or current proportional to the sensed current. A specific aspect of the magnetic sensor can include a low-offset, linear Hall circuit with a copper conduction path located near a surface of a die. Applied current flowing through this copper conduction path can generate a magnetic field which is converted into a proportional voltage.

The system 200 may include an OR gate 206 with N+1 inputs for integrating fault signals from both hardware and software paths 201 and 202. The N inputs may come from the outputs of the timers in the hardware path 201 representing fault conditions detected at different levels of severity. The +1 input or additional input may come from the firmware's fault detection logic in the software path 202. The OR gate 206 may ensure that a relevant condition is satisfied before a fault is confirmed and passed to the SR latch 207. By combining hardware and software signals, the OR gate 206 may ensure that immediate hardware faults take precedence while still integrating the flexibility of software detection. The modular design of the OR gate 206 may allow for expansion by adding more levels of hardware detection. The SR latch (Set-Reset Flip-Flop) 207 may be the final decision-making element in the system 200. The SR latch 207 may have a set input(S), a reset input (R), an output (Q), and a complimentary output (Q). The set input may be coupled to the output of the OR gate 206, which indicates a validated fault condition. The reset input may be coupled to the output of the firmware, and may clear the fault condition, triggered by system recovery or manual intervention. Once a fault condition is detected and passed to the SR latch 207, the output may remain active until the fault is cleared by a reset signal. This may ensure a persistent and reliable response to faults. The output may control the MOSFET gate driver, determining whether to reduce the drive strength or completely disable the circuit to prevent damage. The complimentary output may provide additional logic control for other system components.

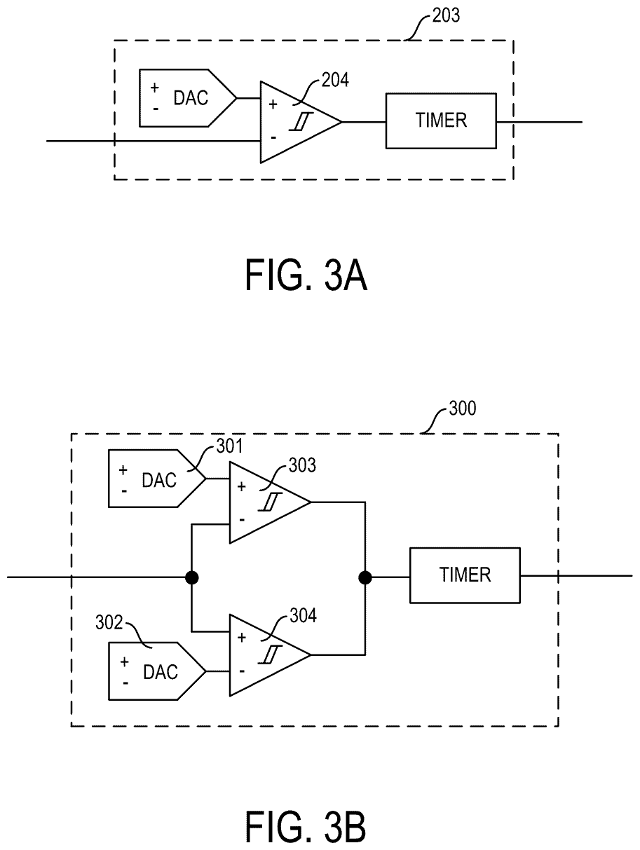

FIG. 3A shows the fault detection unit (FDU) 203 according to FIG. 2. The FDU 203 configuration of FIG. 3A may be designed for applications where current flows in a single direction, such as in DC circuits. It may use a simple comparator setup with a single reference for fault detection. As shown in FIG. 3A, the FDU 203 may include a digital-to-analog converter (DAC), a comparator 204, and a timer (TIMER). The DAC may set a fixed threshold level for current monitoring. This reference voltage may correspond to the maximum allowable current for the system 200. The comparator 204 may compare the current-derived voltage from the circuit (e.g., across a current sensing element 205) against the DAC reference. When the current exceeds the threshold, the comparator 204 may output a fault signal. The timer may ensure that the fault condition persists for a predefined duration before the system acts. This may prevent transient spikes or noise from triggering fault responses.

During operation, current may flow through the system 200, and the corresponding voltage may be fed into the comparator 204. The comparator 204 may continuously compare this voltage to the DAC reference. If the current exceeds the threshold for the duration defined by the timer, a fault signal may be generated.

FIG. 3B shows a fault detection unit (FDU) 300 according to one or more examples. The FDU 300 configuration of FIG. 3B may be suitable for circuits with bi-directional current flow, such as AC or reversible DC systems. It may employ a window comparator setup with two reference levels for enhanced monitoring. As shown in FIG. 3B, the FDU 300 may include two DACs 301 and 302, two comparators 303 and 304, and a timer (TIMER). One DAC 301 may set the upper threshold (positive direction), while the other DAC 302 may set the lower threshold (negative direction) for current monitoring. The first comparator 303 may monitor current in the positive direction by comparing the current signal to the upper threshold. The second comparator 304 may monitor current in the negative direction by comparing the current signal to the lower threshold. The shared timer may ensure that sustained fault conditions trigger a response, similar to the uni-directional configuration.

During operation, the current signal may be fed into both comparators 303 and 304. The comparators 303 and 304 may evaluate whether the current exceeds the upper threshold (positive direction) or drops below the lower threshold (negative direction). If either condition persists for the duration defined by the timer, a fault signal may be generated.

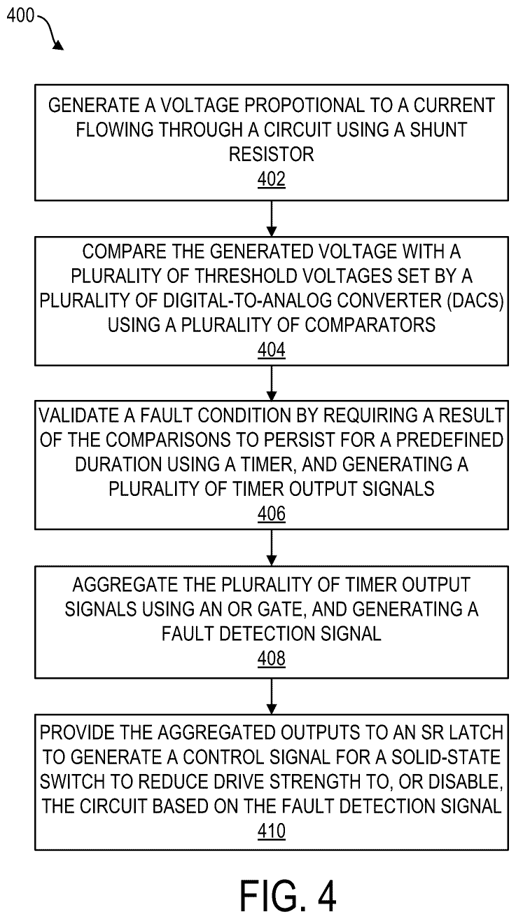

FIG. 4 shows a method 400 of detecting and responding to over-current conditions in a SSCB system according to one or more examples. It is to be appreciated that more or fewer operations than those shown in FIG. 4 may be performed. Further, some of the operations can be performed simultaneously, or in a different order than shown in FIG. 4, as will be understood by a person of ordinary skill in the art. Method 400 can be implemented by systems related to system 200 and operations caused by a computing device. However, method 400 is not limited to that example aspect.

In operation 402, a voltage proportional to a current flowing through a circuit is generated using a shunt resistor. In some aspects, the voltage can be generated using a magnetic sensor instead of a shunt resistor. In operation 404, the generated voltage is compared with a plurality of threshold voltages set by a plurality of digital-to-analog converter (DACs) using a plurality of comparators. One or more of the plurality of threshold voltages set by the plurality of DACs can be adjustable. One or more of the plurality of comparators can include hysteresis to reduce false triggering due to transient current fluctuations. A first comparator of the plurality of comparators can monitor current in a first direction and a second comparator of the plurality of comparators can monitor current in a second direction.

In operation 406, a fault condition is validated by requiring a result of the comparisons to persist for a predefined duration using a timer, and generating a plurality of timer output signals. In operation 408, the plurality of timer output signals is aggregated using an OR gate, and a fault detection signal is generated. In operation 410, the aggregated outputs are provided to an SR latch to generate a control signal for a solid-state switch to reduce drive strength to, or disable, the circuit based on the fault detection signal.

Some aspects of method 400 can include sampling voltage across the shunt resistor using an analog-to-digital converter (ADC) and processing the sampled voltage using firmware to detect additional fault conditions. The firmware can be configured to adjust fault detection thresholds based on historical fault data or load conditions. Some aspects of method 400 can include resetting the SR latch based on an output of the firmware.

Various examples have been disclosed herein, in connection with the above description and the drawings. It will be understood that it would be unduly repetitious to literally describe and illustrate every combination and subcombination of these examples. Accordingly, all examples can be combined in any way or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A solid-state circuit breaker (SSCB) system, the system comprising:
a shunt resistor to generate a voltage proportional to a current flowing through a circuit;
a plurality of fault detection units, each fault detection unit comprising:
a digital-to-analog converter (DAC) to set a threshold voltage;
a comparator to compare the voltage generated by the shunt resistor with the threshold voltage set by the DAC; and
a timer to validate a fault condition and generate a timer output signal based on an output of the comparator;
an OR gate to receive the timer output signals from the plurality of fault detection units and generate a fault detection signal; and
an SR latch having a set input to receive the fault detection signal from the OR gate, the SR latch configured to provide a control signal to a gate driver of a solid-state switch based on the fault detection signal.

2. The system of claim 1, wherein the plurality of fault detection units are configured to detect multiple levels of over-current conditions.

3. The system of claim 1, wherein the comparator includes hysteresis to prevent false triggering due to transient current fluctuations.

4. The system of claim 1, the system comprising:
an analog-to-digital converter (ADC) to continuously sample the voltage across the shunt resistor; and firmware to analyze an output of the ADC to detect over-current conditions that do not meet predefined hardware thresholds, and output a firmware output signal indicating whether an over-current condition exists.

5. The system of claim 4, wherein the OR gate is configured to receive the firmware output signal and output the fault detection signal based on the timer output signals and the firmware output signal.

6. The system of claim 5, wherein the SR latch comprises a reset input configured to reset the SR latch based on the firmware output signal.

7. The system of claim 1, wherein each fault detection unit comprises two DACs and two comparators respectively coupled to the two DACs to monitor current in positive and negative directions.

8. The system of claim 1, wherein each DAC in the fault detection units is programmable to adjust the threshold voltage.

9. The system of claim 1, wherein the control signal is configured to control the gate driver to reduce drive strength during an over-current condition and fully disable the circuit during a short-circuit condition.

10. A method of detecting and responding to over-current conditions in a solid-state circuit breaker (SSCB) system, the method comprising:
generating a voltage proportional to a current flowing through a circuit using a shunt resistor;
comparing the generated voltage with a plurality of threshold voltages set by a plurality of digital-to-analog converter (DACs) using a plurality of comparators;
validating a fault condition by requiring a result of the comparisons to persist for a predefined duration using a timer, and generating a plurality of timer output signals;
aggregating the plurality of timer output signals using an OR gate, and generating a fault detection signal; and
providing the aggregated outputs to an SR latch to generate a control signal for a solid-state switch to reduce drive strength to, or disable, the circuit based on the fault detection signal.

11. The method of claim 10, wherein a first comparator of the plurality of comparators monitors current in a first direction and a second comparator of the plurality of comparators monitors current in a second direction.

12. The method of claim 10, wherein one or more of the plurality of threshold voltages set by the plurality of DACs are adjustable.

13. The method of claim 10, wherein one or more of the plurality of comparators includes hysteresis to reduce false triggering due to transient current fluctuations.

14. The method of claim 10, the method further comprising sampling voltage across the shunt resistor using an analog-to-digital converter (ADC) and processing the sampled voltage using firmware to detect additional fault conditions.

15. The method of claim 14, wherein the firmware is configured to adjust fault detection thresholds based on historical fault data or load conditions.

16. The method of claim 10, comprising resetting the SR latch based on an output of the firmware.

17. A solid-state circuit breaker (SSCB) system, the system comprising:
a current sensing element to generate a voltage proportional to a current flowing through a circuit;
a plurality of hardware-based signal paths configured to receive the voltage generated by the current sensing element and detect faults based on a plurality of respective thresholds;
a software-based signal path configured to receive the voltage generated by the current sensing element and detect faults outside of the plurality of thresholds;
a logic gate to aggregate outputs from the plurality of hardware-based signal paths and the software-based signal path; and
an SR latch to provide a control signal to a gate driver of a solid-state switch based on an output from the logic gate.

18. The system of claim 17, wherein the output of the software-based signal path is configured to reset the SR latch.

19. The system of claim 17, wherein one or more of the plurality of hardware-based signal paths are configured to monitor current in the circuit in a first direction and a second direction that is opposite the first direction.

20. The system of claim 17, wherein the plurality of hardware-based signal paths are configured to detect faults based on the voltage generated by the current sensing element exceeding the one or more of the plurality of respective thresholds for a predefined duration.

21. The system of claim 17, wherein the current sensing element is a shunt resistor or a magnetic sensor.
